(19) United States
(12) Patent Application Publication
(10) Pub. No.: US 2003/0060014 A1
(43) Pub. Date: Mar. 27, 2003

(54) Field effect transistor configuration with high latch-up resistance, and method for its production

(76) Inventors: Thomas Neidhart, Klagenfurt (AT); Carsten Schaeffer, Treffen B. Villach (AT); Guenter Schagerl, Villach (AT)

Correspondence Address: LERNER AND GREENBERG, P.A., Post Office Box 2480, Hollywood, FL, 33022-2480, US

(21) Appl. No.: 10/229,980

(22) Filed: Aug. 28, 2002

Related U.S. Application Data
(63) Continuation of application No. PCT/DE01/00617, filed on Feb. 14, 2001.

(30) Foreign Application Priority Data
Feb. 28, 2000 (DE) 100 09 345.0

(51) Int. Cl. H01L 21/336; H01L 29/76; H01L 29/94; H01L 31/062; H01L 31/119

(52) U.S. Cl. 438/270; 257/328; 257/330; 438/268

(57) ABSTRACT

A field effect transistor configuration includes extending the source region along a trench and below the highly doped base region in a self-adjusting manner to increase the latch-up strength.

### CROSS-REFERENCE TO RELATED APPLICATION

This application is a continuation of copending International Application No. PCT/DE01/00617, filed Feb. 14, 2001, which designated the United States and was not published in English.

### BACKGROUND OF THE INVENTION

Field of the Invention

The present invention relates to a field effect transistor configuration having a gate electrode in the form of a trench, with:

a semiconductor substrate of a first conductance type;

at least one trench, which extends from a first surface of the semiconductor substrate into the semiconductor substrate;

an insulation layer that covers the walls of the at least one trench;

a conductive material that fills the trench and forms a gate electrode;

a source region of the first conductance type, which is disposed along the trench and extends from the first surface of the semiconductor substrate into the semiconductor substrate;

a body region of a second conductance type, which is of the opposite conductance type to the first conductance type, with the body region extending under the source region and being adjacent to the trench;

a drain region of the first conductance type, which is adjacent to the body region; and

at least one highly doped region of the second conductance type in the body region, which is disposed at least partially under the source region and is at the same time adjacent to the source region.

The invention also relates to a method for production of such a field effect transistor configuration.

A field effect transistor configuration of the type mentioned initially, in which the highly doped region of the second conductance type is additionally at least partially adjacent to the trench, is disclosed in International Patent Application PCT/DE98/03747.

The expression a “field effect transistor configuration” as set forth herein includes, for example, MOSFET transistors and insulated gate bipolar transistors (IGBT) both above and in the following text.

IGBTs, in particular, are subject to particularly stringent requirements with regard to their capability to disconnect over currents and their latch-up resistance, for use in modules for traction or converter applications. The capability of IGBTs to disconnect over currents is, in general, limited by the triggering of a parasitic thyristor in the IGBT.

Conventional IGBT technologies nowadays preferably use trench technology to produce individual IGBT cells. This also applies to the field effect transistor configuration described in the above International Patent Application PCT/DE98/03747.

The trench allows the charge carrier density to be increased on the front face, that is to say, in the region of the source, and such increase considerably improves the forward characteristics of the transistor configuration.

### SUMMARY OF THE INVENTION

It is accordingly an object of the invention to provide a field effect transistor configuration with high latch-up resistance, and a method for its production that overcomes the hereinafore-mentioned disadvantages of the heretofore-known devices and methods of this general type and that is distinguished by high latch-up resistance and can also be produced largely by a simple, self-adjusting technological process procedure.

With the foregoing and other objects in view, there is provided, in accordance with the invention, a field effect transistor configuration, including a semiconductor substrate of a first conductance type, the semiconductor substrate having a first surface, at least one trench extending from the first surface into the semiconductor substrate, the at least one trench having walls, an insulation layer covering the walls, a conductive material filling the at least one trench and forming a gate electrode, a source region of the first conductance type, the source region being disposed along the at least one trench and extending from the first surface into the semiconductor substrate, a body region of a second conductance type opposite the first conductance type, the body region being adjacent to the at least one trench and extending under the source region, a drain region of the first conductance type, the drain region being adjacent to the body region, at least one doped region of the second conductance type in the body region, the at least one doped region being adjacent to the source region and simultaneously being disposed at least partially under the source region, and the source region extending from the first surface along the at least one trench to underneath the at least one doped region.

According to the invention, a field effect transistor configuration of the type mentioned initially extends the source region from the first surface of the semiconductor substrate, along the trench to underneath the highly doped region of the second conductance (also referred to as conductivity) type in the body region.

Because the source region extends from the first surface of the semiconductor substrate along the trench to underneath the highly doped region of the second conductance type in the body region, the source region has an “angled” profile. In such a case, the layer thickness of the source region along the trench is less than about 500 nm, in particular, between 200 nm and 500 nm. Flat doped regions such as these can be produced by ion implantation close to the surface. If, as is normal, the semiconductor substrate is composed of silicon, then, by way of example, ion implantation is possible down to a depth of below 100 nm, and this is followed by heat treatment to anneal the crystal lattice, during which the layer thickness mentioned above of up to 500 nm is then achieved.

In accordance with another feature of the invention, the at least one trench has a side wall adjacent the body region, the conductive material has an edge adjacent the side wall, and the edge of the conductive material is etched back from the side wall into the conductive material to a distance between 200 nm and 1000 nm.

In accordance with a further feature of the invention, the etch back of the edge of the conductive material has an aperture angle greater than approximately 30°.

Due to the angled doping profile, the highly doped region of the second conductance type has a lower edge that is deeper than the lower edge of the source region in the area beyond the wall of the trench. In such a case, the doping concentration in the highly doped region of the second conductance type is considerably greater than in the body region of the second conductance type, but is not so high that the source region doping on the surface and on the wall of the trench is changed. The field effect transistor configuration according to the invention is also distinguished by a very small distance of less than about 500 nm between the highly doped region of the second conductance type and the MOS channel, which runs along the side wall of the trench, in the body region. This short distance is produced by self-adjusting process control, as will be explained in more detail further below.

The field effect transistor configuration according to the invention and, in particular, the source region with the angled doping profile, can be produced in various ways. However, it is particularly advantageous for the conductive material that fills the trench first of all to be etched back on the face adjacent to the body region, and for source implantation then to be carried out at an oblique incidence angle. During the process of partially etching back the conductive material that fills the trench, and that may, in particular, be doped polycrystalline silicon, care should be taken to ensure that an aperture angle between the front edge of the remaining conductive material on the face adjacent to the body region and the front edge of the conductive material that is not etched back is greater than about 30° with respect to the vertical to the surface of the semiconductor substrate.

In accordance with an added feature of the invention, the at least one trench has a side wall adjacent the body region, the conductive material has an edge adjacent the side wall, and a portion of the edge is recessed from the side wall into the conductive material to a distance between 200 nm and 1000 nm.

In accordance with an additional feature of the invention, the recess of the edge of the conductive material has an aperture angle greater than approximately 30°.

In accordance with yet another feature of the invention, the at least one doped region is formed by ion implantation and subsequent annealing/diffusion.

In accordance with yet a further feature of the invention, the source region is formed by ion implantation and subsequent annealing/diffusion.

In accordance with yet an added feature of the invention, the source region is formed by deposition.

In accordance with yet an additional feature of the invention, the semiconductor substrate, the at least one trench, the insulation layer, the conductive material, the source region, the body region, the drain region, and the at least one doped region form an IGBT with a latch-up resistance.

With the objects of the invention in view, there is also provided an IGBT having latch-up resistance, including a semiconductor substrate of a first conductance type, the semiconductor substrate having a first surface, at least one trench extending from the first surface into the semiconductor substrate, the at least one trench having walls, an insulation layer covering the walls, a conductive material filling the at least one trench and forming a gate electrode, a source region of the first conductance type, the source region being disposed along the at least one trench and extending from the first surface into the semiconductor substrate, a body region of a second conductance type opposite the first conductance type, the body region being adjacent to the at least one trench and extending under the source region, a drain region of the first conductance type, the drain region being adjacent to the body region, at least one doped region of the second conductance type in the body region, the at least one doped region being adjacent to the source region and simultaneously being disposed at least partially under the source region, and the source region extending from the first surface along the at least one trench to underneath the at least one doped region.

With the objects of the invention in view, there is also provided a field effect transistor configuration, including a semiconductor substrate of a first conductance type, the semiconductor substrate having a first surface, at least one trench extending from the first surface into the semiconductor substrate, the at least one trench having walls, an insulation layer covering the walls, a conductive material filling the trench and forming a gate electrode, a source region of the first conductance type, the source region being disposed along the trench and extending from the first surface into the semiconductor substrate, a body region of a second conductance type opposite the first conductance type, the body region being adjacent to the trench and extending under the source region, a drain region of the first conductance type, the drain region being adjacent to the body region, at least one highly doped region of the second conductance type in the body region, the at least one highly doped region being adjacent to the source region and simultaneously being disposed at least partially under the source region, and the source region extending from the first surface along the trench to underneath the at least one highly doped region.

With the objects of the invention in view, there is also provided a method of producing a field effect transistor, including the steps of providing a semiconductor substrate having a first surface and a first conductance type, extending at least one trench from the first surface into the semiconductor substrate, covering walls of the at least one trench with an insulation layer, forming a gate electrode by filling the at least one trench with a conductive material, producing a source region of the first conductance type along the at least one trench and extending the source region from the first surface into the semiconductor substrate by implantation at an oblique incidence angle, disposing a body region of a second conductance type opposite the first conductance type adjacent to the at least one trench and extending the body region under the source region, etching back the conductive material filling the at least one trench on a face of the at least one trench adjacent to the body region, disposing a drain region of the first conductance type adjacent to the body region, disposing at least one doped region of the second conductance type in the body region adjacent to the source region and simultaneously at least partially under the source region, and extending the source region from the first surface along the at least one trench to underneath the at least one doped region.

In accordance with again another mode of the invention, the source region is produced by implantation at an oblique incidence angle. Preferably, the incidence angle is with respect to the first surface. In particular, the incidence angle is between approximately 30° and 45°.

In accordance with again a further mode of the invention, the etching step is carried out to locate an edge of the conductive material at a depth of between approximately 0.2 μm and 1.0 μm.

In accordance with again an added mode of the invention, the etching of the conductive material is carried out in two partial etching steps.

Once the conductive material that fills the trench has been partially etched back as such, in accordance with again an additional mode of the invention, the source implantation is preferably carried out at an oblique incidence angle, thus resulting in the already mentioned angled doping profile for the source region on the surface of the semiconductor substrate and on the side wall of the trench. However, instead of such source implantation at an oblique incidence angle, the source region may also be doped by a furnace deposition process, by which the desired angled doping profile is likewise achieved.

In accordance with still another mode of the invention, the highly doped region of the second conductance type is preferably likewise produced by ion implantation. In such a case, the lower edge of this highly doped region of the second conductance type is located deeper than the lower edge of the source region in an area beyond the wall of the trench, as has already been mentioned above.

In accordance with a concomitant mode of the invention, the first conductance type is preferably the n conductance type; thus, the preferred second conductance type is the p conductance type. The stated conductance types may, of course, also be reversed, however.

Other features that are considered as characteristic for the invention are set forth in the appended claims.

Although the invention is illustrated and described herein as embodied in a field effect transistor configuration with high latch-up resistance, and a method for its production, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1 is a fragmentary, cross-sectional view of an IGBT as one exemplary embodiment of the field effect transistor configuration according to the invention;

FIGS. 2 to 5 are fragmentary cross-sectional views illustrating successive method steps according to the invention for producing a portion of a first exemplary embodiment of the field effect transistor configuration of FIG. 1;

FIGS. 6 to 9 are fragmentary cross-sectional views illustrating successive method steps according to the invention for producing a portion of a second exemplary embodiment of the field effect transistor configuration of FIG. 1; and

FIGS. 10 to 13 are fragmentary cross-sectional views illustrating successive method steps according to the invention for producing a portion of a third exemplary embodiment of the field effect transistor configuration of FIG. 1.

### DESCRIPTION OF THE PREFERRED EMBODIMENTS

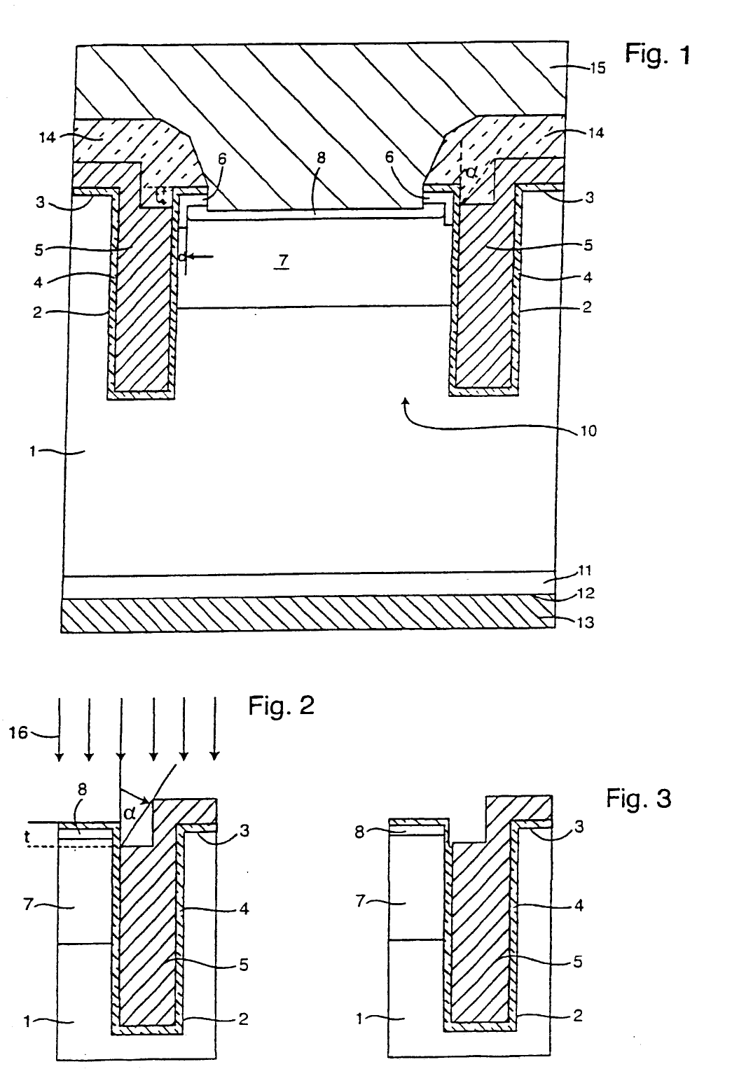

Referring now to the figures of the drawings in detail and first, particularly to FIG. 1 thereof, there is shown a schematic illustration of one exemplary embodiment of an IGBT according to the invention.

Trenches 2, which are introduced into the substrate region 1 by etching, for example, are located in an n⁻-conductive substrate region 1 composed of silicon, which forms an n⁻-conductive base for the IGBT. The walls of these trenches 2 are filled with an insulation layer 4 composed, for example, of silicon dioxide, which also extends on a first surface 3 of the substrate region 1. A p-conductive base is introduced into the surface region between the trenches 2, and represents a body region 7 of the field effect transistor configuration.

A p⁺-conductive highly doped region 8 as well as (at its edge, adjacent to the insulation layer 4) an n⁺-conductive source region 6, are also provided in the surface area between the trenches 2, which source region 6 has an angled doping profile and extends from the first surface 3 along the trench 2 to underneath the p⁺-conductive region 8 in the body region 7.

The trenches 2 are filled on the insulation layer 4 with a conductive material 5, which is, preferably, doped polycrystalline silicon.

The conductive material 5 is partially etched back. As a result, the side wall of the trench 2 is exposed down to a depth t (200 nm<t<1000 nm). The aperture angle α so formed should be greater than 30°, particularly in the exemplary embodiments shown in FIGS. 2 to 9.

The n⁻-conductive base that includes the substrate region 1 also forms an n⁻-conductive drain region 10 that is disposed on a p-conductive emitter 11 to which rear-face metallization 13, composed, for example, of aluminum is applied, on the second surface 12, which is opposite the first surface 3.

An insulation layer 14 composed, for example, of boron-phosphosilicate glass is also located on the first surface 3, and a window is incorporated therein, through which front-face metallization 15 composed, for example, of aluminum in the window of the insulation layer 14 acts as a trench contact for connection of the source region 6 and of the highly doped region 8.

Three exemplary embodiments of a method for production of the field effect transistor configuration according to the invention will also be explained in the following text with reference to FIGS. 2 to 13.

So-called “tilted source implantation” is carried out in the first exemplary embodiment, which is shown in FIGS. 2 to 5.

First of all, as is illustrated in FIG. 2, the conductive material 5 is partially removed by defined overetching, so that the edge of the conductor material 5 (“polyedge”) is located at a depth t of 0.2 μm to 1.0 μm, and an aperture angle α is produced. The highly doped region 8 is then formed by ion implantation of boron at an incidence angle of 0° to the normal on the surface 3, as is indicated by arrows 16 (“implantation of the p⁺-conductive region 8”). The dose for the ion implantation is chosen such that the p⁺-conductive highly doped region in the vicinity of the surface has its doping reversed during a subsequent source implantation process to produce the source region 6.

The step is then followed by isotropic thinning of the insulation layer 4 to a residual thickness of 10 nm to 40 nm to reduce the layer thickness of the gate oxide, and to make it possible to implant the source region (see FIG. 3).

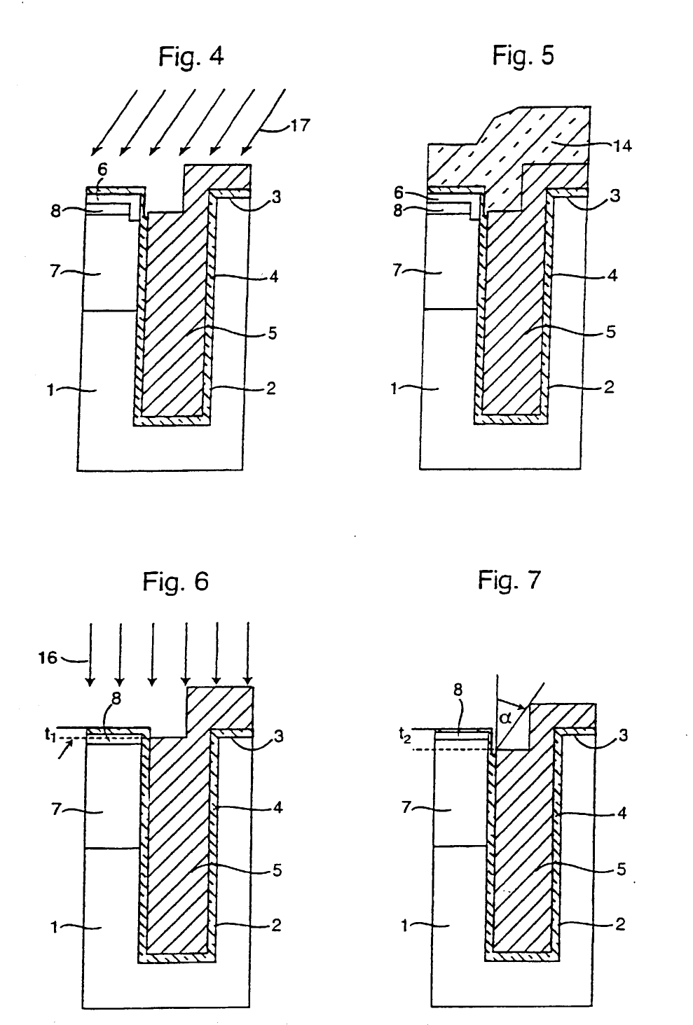

Ion implantation, preferably, using arsenic and/or phosphorus, is then carried out at a tilt angle of 30 to 45° to the normal to the surface 3 to produce the source region 6 (see FIG. 4). With respect to a plan view or orientation of the cross-sectional view of FIG. 4, such implantation is carried out from all four sides of a rectangle or square (“quad mode”) so that the four sides of a trench cell that has a square plan elevation or is rectangular are implanted. Arrows 17 in FIG. 4 illustrate the implantation at the tilt angle of 30 to 45° for the source region 6.

After annealing and/or diffusion for the highly doped regions 8 and for the source region 6 such that the highly doped region 8 is not diffused more deeply than the source region 6 on the wall of the trench 2, the front face metallization 15 is, finally, also applied.

It should be noted that, in this exemplary embodiment, the steps up to production of the structure as shown in FIG. 2 and the steps that still need to be carried out after completion of the structure shown in FIG. 5 are respectively carried out conventionally. Thus, such steps do not need to be explained in any more detail here.

The exemplary embodiment in FIGS. 2 to 5, allows self-adjusting production of the source region 6 by the tilted implantation (see arrows 17). In this exemplary embodiment, as well as in the following exemplary embodiments, the layer thickness d (see FIG. 1) of the source region 6 along the wall of the trench 2 is in the range less than 500 nm so that the distance between the highly doped region 8 and the MOS channel on the side wall of the trench 2 is extremely short, and this distance can be set without any problems by the self-adjusting process control through the tilt angle of the implantation and the implantation energy (see arrows 17 in FIG. 4).

FIGS. 6 to 9 show a second exemplary embodiment of the method according to the invention, in which “tilted source implantation with second recess etching” is carried out.

In a similar way to that in the first exemplary embodiment as shown in FIGS. 2 to 5, the conductive material 5, that is to say, the polycrystalline silicon, is first of all etched with defined overetching so that the polyedge is located at a depth t1 that is less than 0.2 μm. The step is then followed by implantation of boron at an incidence angle of 0° to produce the highly doped region 8, with the doping dose being chosen, once again, such that the subsequent source implantation changes the doping of the highly doped region 8 in the vicinity of the surface. This maintains the structure as shown in FIG. 6.

Second recess etching of the conductive material 5 follows so that the polyedge in the trench 2 is located at a depth t2 of 0.2 to 1.0 μm (see FIG. 7). The aperture angle α is in such a case greater than about 30°, as in the first exemplary embodiment.

The following method steps are similar to those for the exemplary embodiment shown in FIGS. 2 to 5: the gate oxide, that is to say, the insulation layer 4, is thinned isotropically in the exposed area to a residual thickness of 10 nm to 40 nm, and the thinning can be done by etching. The source region 6 is then implanted, and the implantation is done from all sides at a tilt angle of 30 to 45° (see FIG. 8), so that the four sides of the trench cell, which has square plan elevation or is rectangular, are implanted.

The step is followed by conventional annealing/diffusion for the highly doped region 8 and for the source region 6 such that the highly doped region 8 is not diffused deeper than the source region 6 on the wall of the trench 2.

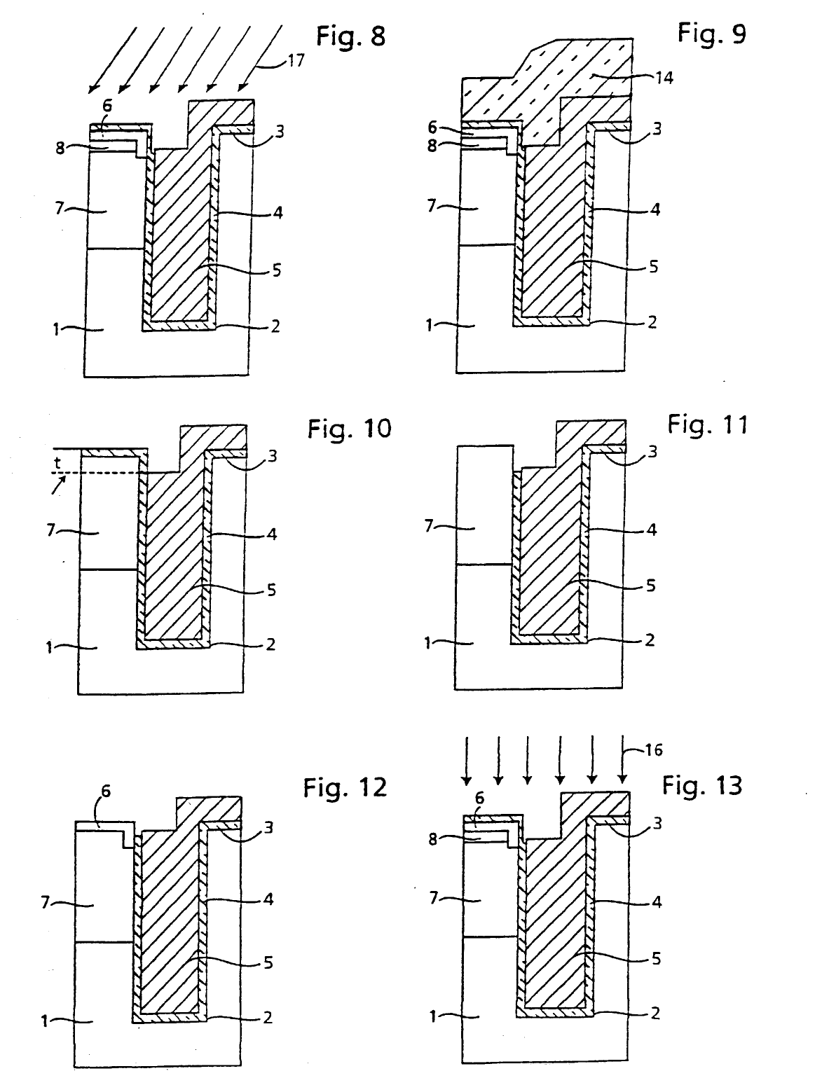

Finally—as in the exemplary embodiment shown in FIGS. 2 to 5—the front face metallization 15 that is composed, for example of aluminum, is also applied finally to obtain the structure shown in FIG. 9.

As in the exemplary embodiment shown in FIGS. 2 to 5, the steps to produce the structure as shown in FIG. 6 and the steps that are also carried out on the structure as shown in FIG. 9 are also of a conventional type in the exemplary embodiment shown in FIGS. 6 to 9.

Finally, FIGS. 10 to 13 show a further exemplary embodiment of the method according to the invention.

First of all, as in the exemplary embodiments shown in FIGS. 2 to 5, and in FIGS. 6 to 9, the conductive material is etched, that is to say, the doped polycrystalline silicon layer in the trench 2, with defined overetching such that the polyedge is located at a depth t of about 0.4 to 1.0 μm (see FIG. 10).

The step is followed by isotropic etching of the insulation layer 4, that is to say, of the gate oxide, as far as the body region 7 (see FIG. 11), or to a small residual thickness, so that the source region 6 can then be diffused in by a deposition process. Arsenic and/or phosphorus are preferably used for this deposition process, and are diffused in to a depth from about 100 nm to a maximum of 400 nm, which results in the structure as shown in FIG. 12 having the source region 6.

The step is followed by oxidation of stray oxide on the surface of the source region 6. The highly doped region 8 is then produced by ion implantation of boron at an incidence angle of 0° to the normal to the surface 3 (see arrows 16 in FIG. 13), with the implantation dose being chosen such that the source region 6 does not have its doping reversed in the vicinity of the surface.

The step is also followed by the conventional annealing and diffusion steps in the exemplary embodiments in FIGS. 2 to 5 and 6 to 9 for the highly doped region 8 and for the source region 6 such that the highly doped region 8 is not diffused deeper than the source region 6 on the wall of the trench 2.

We claim:

1. A field effect transistor configuration, comprising:
a semiconductor substrate of a first conductance type, said semiconductor substrate having a first surface;
at least one trench extending from said first surface into said semiconductor substrate, said at least one trench having walls;
an insulation layer covering said walls;
a conductive material filling said at least one trench and forming a gate electrode;
a source region of said first conductance type, said source region being disposed along said at least one trench and extending from said first surface into said semiconductor substrate;
a body region of a second conductance type opposite said first conductance type, said body region being adjacent to said at least one trench and extending under said source region;
a drain region of said first conductance type, said drain region being adjacent to said body region;
at least one doped region of said second conductance type in said body region, said at least one doped region being adjacent to said source region and simultaneously being disposed at least partially under said source region; and
said source region extending from said first surface along said at least one trench to underneath said at least one doped region.

2. The field effect transistor configuration according to claim 1, wherein said source region along said at least one trench has a layer thickness not greater than 500 nm.

3. The field effect transistor configuration according to claim 1, wherein said source region along said at least one trench has a layer thickness between 200 nm and 500 nm.

4. The field effect transistor configuration according to claim 1, wherein:
said at least one trench has a side wall adjacent said body region;
said conductive material has an edge adjacent said side wall; and
said edge of said conductive material is etched back from said side wall into said conductive material to a distance between 200 nm and 1000 nm.

5. The field effect transistor configuration according to claim 4, wherein said etch back of said edge of said conductive material has an aperture angle greater than approximately 30°.

6. The field effect transistor configuration according to claim 1, wherein:
said at least one trench has a side wall adjacent said body region;
said conductive material has an edge adjacent said side wall; and
a portion of said edge is recessed from said side wall into said conductive material to a distance between 200 nm and 1000 nm.

7. The field effect transistor configuration according to claim 4, wherein said recess of said edge of said conductive material has an aperture angle greater than approximately 30°.

8. The field effect transistor configuration according to claim 1, wherein said at least one doped region is ion implanted and annealed/diffused.

9. The field effect transistor configuration according to claim 1, wherein said at least one doped region is formed by ion implantation and subsequent annealing/diffusion.

10. The field effect transistor configuration according to claim 1, wherein said source region is ion implanted and annealed/diffused.

11. The field effect transistor configuration according to claim 1, wherein said source region is formed by ion implantation and subsequent annealing/diffusion.

12. The field effect transistor configuration according to claim 1, wherein said source region is a deposited source region.

13. The field effect transistor configuration according to claim 1, wherein said source region is formed by deposition.

14. The field effect transistor configuration according to claim 1, wherein said semiconductor substrate, said at least one trench, said insulation layer, said conductive material, said source region, said body region, said drain region, and said at least one doped region form an IGBT with a latch-up resistance.

15. An IGBT having latch-up resistance, comprising:
a semiconductor substrate of a first conductance type, said semiconductor substrate having a first surface;
at least one trench extending from said first surface into said semiconductor substrate, said at least one trench having walls;
an insulation layer covering said walls;
a conductive material filling said at least one trench and forming a gate electrode;
a source region of said first conductance type, said source region being disposed along said at least one trench and extending from said first surface into said semiconductor substrate;
a body region of a second conductance type opposite said first conductance type, said body region being adjacent to said at least one trench and extending under said source region;
a drain region of said first conductance type, said drain region being adjacent to said body region;
at least one doped region of said second conductance type in said body region, said at least one doped region being adjacent to said source region and simultaneously being disposed at least partially under said source region; and
said source region extending from said first surface along said at least one trench to underneath said at least one doped region.

16. A field effect transistor configuration, comprising:
a semiconductor substrate of a first conductance type, said semiconductor substrate having a first surface;
at least one trench extending from said first surface into said semiconductor substrate, said at least one trench having walls;
an insulation layer covering said walls;
a conductive material filling said trench and forming a gate electrode;
a source region of said first conductance type, said source region being disposed along said trench and extending from said first surface into said semiconductor substrate;
a body region of a second conductance type opposite said first conductance type, said body region being adjacent to said trench and extending under said source region;
a drain region of said first conductance type, said drain region being adjacent to said body region;
at least one highly doped region of said second conductance type in said body region, said at least one highly doped region being adjacent to said source region and simultaneously being disposed at least partially under said source region; and
said source region extending from said first surface along said trench to underneath said at least one highly doped region.

17. A method of producing a field effect transistor, which comprises:
providing a semiconductor substrate having a first surface and a first conductance type;
extending at least one trench from the first surface into the semiconductor substrate;
covering walls of the at least one trench with an insulation layer;
forming a gate electrode by filling the at least one trench with a conductive material;
producing a source region of the first conductance type along the at least one trench and extending the source region from the first surface into the semiconductor substrate by implantation at an oblique incidence angle;
disposing a body region of a second conductance type opposite the first conductance type adjacent to the at least one trench and extending the body region under the source region;
etching back the conductive material filling the at least one trench on a face of the at least one trench adjacent to the body region;
disposing a drain region of the first conductance type adjacent to the body region;
disposing at least one doped region of the second conductance type in the body region adjacent to the source region and simultaneously at least partially under the source region; and
extending the source region from the first surface along the at least one trench to underneath the at least one doped region.

18. The method according to claim 17, which further comprises producing the source region by implantation at an oblique incidence angle with respect to the first surface.

19. The method according to claim 18, which further comprises producing the source region by implantation at an incidence angle of between approximately 30° and 45° with respect to the first surface.

20. The method according to claim 17, which further comprises producing the source region by implantation at an incidence angle between approximately 30° and 45°.

21. The method according to claim 17, which further comprises carrying out the etching step to locate an edge of the conductive material at a depth of between approximately 0.2 μm and 1.0 μm.

22. The method according to claim 17, which further comprises carrying out the etching of the conductive material in two partial etching steps.

23. The method according to claim 17, which further comprises producing the source region with a furnace deposition process.

24. The method according to claim 17, which further comprises producing the at least one doped region by ion implantation.
